(19) United States
(12) Patent Application Publication
(10) Pub. No.: US 2019/0006546 A1
(43) Pub. Date: Jan. 3, 2019

(54) OPTICAL DEVICE FOR REDUCING THE VISIBILITY OF ELECTRICAL INTERCONNECTIONS IN SEMI-TRANSPARENT THIN-FILM PHOTOVOLTAIC MODULES

(71) Applicant: Sunpartner Technologies, Rousset (FR)

(72) Inventor: Rachida Boubekri, Rousset (FR)

(73) Assignee: Sunpartner Technologies, Rousset (FR)

(21) Appl. No.: 16/061,818

(22) PCT Filed: Dec. 12, 2016
(86) PCT No.: PCT/FR2016/000207

§ 371 Date: Jun. 13, 2018

(30) Foreign Application Priority Data
Dec. 16, 2015 (FR) 15 02617

(51) Int. Cl. H01L 31/0468; H01L 31/0465; H01L 31/0463; H01L 31/0224

(52) U.S. Cl. CPC H01L 31/0468; H01L 31/0465; H01L 31/022466; H01L 31/022441; H01L 31/0463

(57) ABSTRACT

The invention relates to thin-film photovoltaic modules which are made semi-transparent by laser ablation or by lithography processes. The transparency areas form a network of repetitive patterns such as a network of circular or hexagonal holes. The electrical insulation lines and the electrical interconnection lines between the cells are positioned at random either in the transparency areas or in the non-transparency areas, and demonstrate visual effects which reduce the homogeneous quality of the photovoltaic module. In order to make them invisible to the naked eye, the electrical insulation lines are positioned in transparency areas arranged in straight bands having high transparency density, and the electrical interconnection lines are positioned in transparency areas arranged in straight bands having low transparency density.

The present invention relates to semitransparent photovoltaic modules formed of thin-film solar cells that are connected to one another by visible electrical insulation and interconnection lines, and more particularly photovoltaic modules whose degree of transparency is achieved by creating a more or less dense array of geometric areas of transparency in the structure of said thin films.

### PRIOR ART

A photovoltaic module is formed of a multitude of photovoltaic cells that are connected in series. Each cell is made up of a stack of thin films positioned in the following order: a transparent substrate (for example organic or mineral glass), and then a transparent conductive front electrode generally made from a transparent conductive oxide, referenced hereinafter using the term ‘TCO’ (acronym for ‘transparent conductive oxide’), and then a photoactive layer, generally called ‘absorber’, and then a conductive back electrode, generally called ‘back contact’, which is often made of metal. The thickness of each thin film varies between a few hundred nanometers and a few microns.

Transparency of photovoltaic modules is highly sought after in the construction industry, and is achieved using various etching and/or lithography methods on the various thin films (as described in U.S. Pat. No. 4,795,500 by Sanyo). More recently, transparency has been achieved using a laser ablation method on said thin films. U.S. Pat. No. 6,858,461 describes a laser ablation technique on lines perpendicular to the electrical insulation and interconnection lines of the cells. Said insulation and interconnection lines are referenced hereinafter using the word ‘scribes’. In patent US 2011/0017280 A, micro-holes are formed in the structure of the cells and the diameter of the holes depends on the energy and on the diameter of the laser beam; this diameter does not exceed 40 μm. To increase transparency, Nexpower (patent U.S. Pat. No. 7,951,725) successively forms, through laser ablation in two different thin films, two superposed holes with different diameters. The smaller one is formed in the transparent electrode (before deposition of the photoactive layer and of the metal), and the second, wider one is formed after deposition of the photoactive layer and of the back metal contact.

In the case of thin-film photovoltaic modules, the scribes are lines, called P1, P2, P3, which are generally formed by a laser. There are other architectures that bring about the phenomenon of transparency and that do not require any ablation (WO 2008/093933 and US 2013/0247969), but there is no description of any particular feature with regard to the optical quality of the device.

If the visual quality of a photovoltaic module is defined by the homogeneity of its transparency, it is also possible to define this quality as the absence, or low visual discernibility, of discontinuities in geometry, colorimetry and contrast that may be able to be seen at its surface by the eye of an observer positioned around 30 cm away. Now, the size and the position of the insulation and interconnection lines of the cells (the scribes) with respect to the areas of transparency create a discontinuity in geometry and contrast that is generally perceived by the eye and impairs the desired visual quality. Such high-level visual quality is mainly desired for photovoltaic glazings.

### AIM OF THE INVENTION

The invention hereinafter describes a device that makes it possible to improve the visual quality of a photovoltaic surface formed of a multitude of thin-film cells connected by electrical insulation and interconnection lines (scribes); this improvement in the visual quality is achieved by making said insulation and interconnection lines less visible, or even invisible, for an observer positioned around 40 cm away from said photovoltaic surface.

### SUMMARY OF THE INVENTION

The subject of the invention is a semitransparent photovoltaic module comprising:
firstly, a stack of thin films including at least one transparent thin film that has the function of a front electrode, a photovoltaic thin film that has the function of an absorber, and a metal thin film that has the function of a back electrode; said thin films being deposited on a transparent substrate; said photovoltaic module being divided into a plurality of cells N,N+1, . . . N+x that are electrically connected to one another by way of electrical interconnection lines P2 forming the junction between the back electrode of the cell N and the front electrode of the cell N+1, and by way of electrical insulation lines forming the insulation P3 between the back electrode of the cell N and of the cell N+1, and the insulation P1 between the front electrode of the cell N and of the cell N+1;
secondly, a multitude of areas of transparency that are formed at least in said back metal electrode and in said absorber photovoltaic thin film; said areas of transparency all having the same geometric shape and being positioned with respect to one another so as to form one or more arrays that give rise to the visual appearance of a multitude of areas in the form of rectilinear strips whose longitudinal axes are parallel; some of said areas of transparency being positioned in strips having a high transparency density and some of said areas of transparency being positioned in a strip having a low transparency density,
characterized in that said electrical insulation lines P1 and P3 are positioned in said rectilinear strips with high transparency density, and said electrical interconnection lines P2 are positioned in said rectilinear strips with low transparency density, so as to reduce the visibility, to the naked eye, of said electrical interconnection and insulation lines P1, P2 and P3.

Specifically, the electrical interconnection lines P2 and the insulation lines P1 and P3 have different colors and transparencies depending on whether or not said lines are positioned in an area of transparency and depending on whether manufacturing is carried out by laser ablation (direct ablation of thin films) or by lithography methods (etching of the films through a mask). Analyzing the various possible cases (see the detailed description of FIGS. 2 and 3 below) shows that the visibility of said lines (P1,P2,P3) is reduced when they are positioned in areas in the form of rectilinear strips whose color or transparency, as the case may be, is similar to their own. One specific typical case is that of a photovoltaic surface whose partial transparency is formed by ablation of an array of areas to form holes having the shape of disks. In this case, the disks must not touch each other so that the electric current is able to flow from one cell to another. The spaces between the holes are aligned and form a multitude of areas in the form of rectilinear strips with low transparency. It is then this area of low transparency in which it is expedient to position the connector P2, which is itself opaque. The insulation lines P1 and P3 are lines that are traced in the front and back electrodes, respectively, and it is then expedient to position these lines in the areas in the form of rectilinear strips with high transparency that are formed along the lines that pass through the center of the ablated areas, in this case the center of the circular holes. In this case, the lines P1 and P3 will be naturally transparent. The requirement for the lines P1, P2 and P3 to be made parallel to one another in order that they do not overlap, and the requirement to create areas in the form of rectilinear strips with low and high transparency in order to allow said lines P1, P2 and P3 to be ‘camouflaged’ better, means that it is mandatory to choose the basic shape and the dimensions (spacing, width, position, degree of transparency) of the array of areas of transparency, on the one hand, and to choose the dimensions in terms of width and in terms of spacing of the three lines P1, P2 and P3, on the other hand, so that all of these elements are combined with one another in a compatible manner and the desired result is achieved.

In one particular embodiment, the geometric shapes of the areas of transparency forming said ordered array are chosen from among the following shapes or in combinations thereof: disks, oval, polygonal, hexagonal and square surfaces. Advantageously, the disks make it possible to minimize the effects of diffraction with respect to the polygonal shapes.

In another particular embodiment, the width of said three electrical insulation and interconnection lines (P1,P2,P3) is less than 100 micrometers. This width makes it possible to easily position the interconnection line P2 in a strip with low transparency, so as not to be visible in an area of transparency.

According to one variant embodiment, the distance between two consecutive electrical insulation or interconnection lines (P1,P2,P3) is greater than 100 micrometers. It is possible to show that, in this configuration, said three lines are at the limit of the resolution capability of the eye, substantially 116 μm for an observation at a distance of more than 40 cm from the module.

In another particular embodiment, the largest dimension of the geometric shapes of said areas of transparency is greater than 400 micrometers. Such dimensions improve the optical quality of the semitransparent photovoltaic module, in particular by reducing blur.

According to another particular embodiment, the smallest dimension of the opaque areas that separate said areas of transparency is less than 100 micrometers.

### DETAILED DESCRIPTION OF THE INVENTION

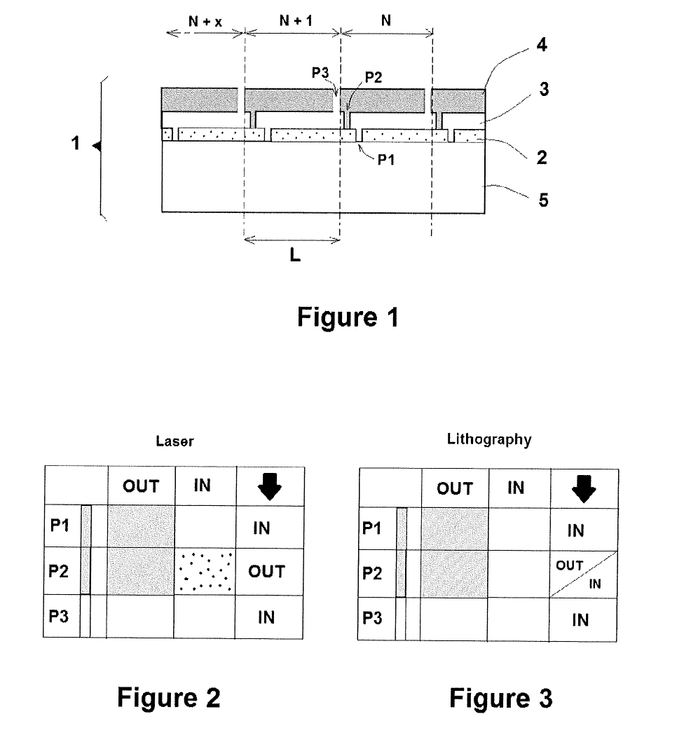

The invention is now described in more detail with the aid of the description of indexed FIGS. 1 to 7.

FIG. 1 is a cross-sectional diagram of a photovoltaic module made from thin films.

FIG. 2 shows a table summarizing the various appearances of the electrical connection lines in the case of transparency being achieved by laser ablation.

FIG. 3 shows a table summarizing the various appearances of the electrical connection lines in the case of transparency being achieved by lithography.

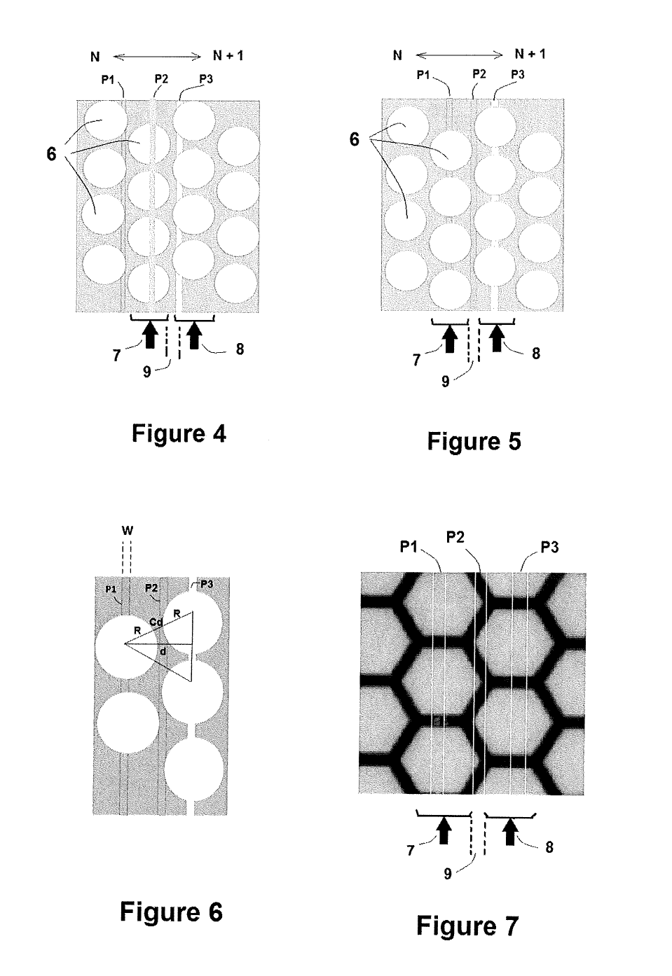

FIG. 4 shows an example of non-optimized positioning of the scribes in the case of a laser ablation or using a lithographic method.

FIG. 5 shows an example of optimized positioning of the scribes, which then become invisible, in the case of a laser ablation or using a lithographic method.

FIG. 6 shows the example of an array of circular areas of transparency and the calculation of the dimensions and of the optimum position of the scribes.

FIG. 7 shows an example of hexagonal areas of transparency in the form of a honeycomb.

FIG. 1 is a cross-sectional depiction of a photovoltaic module (1) and of its components: cells N, N+1, N+X . . . are connected in series mode. All of the cells have an identical width L and are made from the stack of a transparent substrate (5), ordinarily made of glass or of plastic, of a transparent conductive oxide thin film (2), also called front electrode, which is deposited on the transparent substrate (5), an absorber thin film (3), which is a photovoltaic layer, such as for example amorphous silicon, and then a conductive metal thin film (4), called back electrode. The cells (N, N+1, N+x, . . . ) are separated by insulation lines (P1) in the TCO (2), generally formed by laser scribing or by chemical etching associated with a lithography process. A second etch line (P2) is formed in the absorber (3), this then being filled with metal and forming the contact between the back electrode (4) and the front electrode (2) of the cell (N), thereby making it an interconnection line. Insulation lines (P3) are formed in the back electrode (4). For practical reasons, the lines P3 are generally etched as far as the front electrode (2) of the cell (N). The lines P1, P2 and P3 do not have the same color as they are not covered by the same material. Depending on the type of application, the device may be observed either from the side of the back contact (4) or from the side of the transparent substrate (5). If the device is viewed from the metal side (4), the line P1 is covered by the metal (4) and is therefore only very slightly visible, if at all. The line P2 is also covered by metal, but may be visible to a greater extent if the TCO (2)/metal (4) interface is textured, while the line P3 is completely transparent, and therefore contrasted with respect to the metal, thereby making it visible. If the device is viewed from the side of the transparent substrate (5), the line P1 has the color of the photoactive layer (3), the line P2 has that of the metal (4) and the line P3 remains completely transparent. The width of the interconnection and insulation lines (P1,P2,P3) varies between a few tens of microns and about a hundred microns, and the distance between the lines also varies between about ten and about a hundred microns.

FIG. 2 is a table with two entries that applies to laser-etched cells and that gives the correspondence between each of the connection lines P1, P2, P3 (the first column showing their original color) and their possible position outside an area of transparency (OUT) or inside an area of transparency (IN). Each case under consideration gives six combinations, six boxes in which the dark or light tone provides information regarding the visual appearance of each line (P1,P2,P3). It is thus seen that P1 and P2, which are originally opaque, remain dark after ablation when they are outside an area of transparency (OUT), but only P1 becomes transparent in an area of transparency (IN), while P2 remains opaque. P3, which is originally transparent, remains transparent after ablation, both in an area of transparency (IN) and in an area outside transparency (OUT). The fourth column indicates the best optical positioning choice (IN or OUT) for each of the three lines (P1,P2,P3). It will thus be expedient to position P1 and P3 in areas of transparency (IN) and P2 in areas of non-transparency (OUT) so that they are visible as little as possible to the naked eye.

FIG. 3 is a table with two entries that applies to cells produced using lithographic etching methods and that gives the correspondence between each of the connection lines P1, P2, P3 (the first column showing their original color) and their possible position outside an area of transparency (OUT) or inside an area of transparency (IN). Each case under consideration gives six combinations, six boxes in which the dark or light tone provides information regarding the visual appearance of each line (P1,P2,P3). It is thus seen that P1 and P2, which are originally opaque, remain dark after etching when they are outside an area of transparency (OUT) and that P3, which is originally transparent, remains transparent outside this area of transparency (OUT). In contrast, all of the scribes P1, P2 and P3 are transparent in the areas of transparency (IN) after etching. The fourth column indicates the best positioning choice (IN or OUT) for each of the three lines (P1,P2,P3). It will thus be expedient to position P1 and P3 in areas (IN), while it is optically possible to position the lines P2 indiscriminately in areas (IN) or (OUT). However, with P2 being the electrical interconnection line between the front electrode and the back electrode, if it were to be positioned in an area (IN), only part of the line would effectively be used for the interconnection of the two electrodes. This would have the effect of increasing the resistance of the cell and would thus reduce the electrical efficiency of the photovoltaic module. Therefore, the interconnection line P2 should advantageously be positioned outside an area of transparency (OUT) for reasons of electrical production.

It is therefore seen that the best choices for positioning the scribes (column 4), regardless of the method for ablating the module (laser or lithography), are identical.

FIG. 4 shows a junction between two cells N and N+1 in the case where the areas of transparency (6) (in this case disks) are formed by laser ablation and when the position of the scribes is not optimized. In the majority of cases, the incident beam of the laser passes first of all through the transparent substrate. Due to the differences in absorption of the laser beam by the various materials forming the cell, this depending on the wavelength and on the inherent fluence of the laser, some thin films of the cell may be transparent. For example, a green pulsed laser with a wavelength of 532 nm will be used to ablate the photoactive layer. The TCO is transparent to this wavelength of the laser, and the ablation then occurs firstly in the photoactive layer, which pulverizes the low-thickness metal positioned behind. The content of the scribe P1 is ablated at the same time as the photoactive layer if the latter is situated in the area of transparency, while the scribe P2 that contains only metal may not be ablated by the laser (at the same fluence). P2 may therefore remain visible through the area of transparency. This is what this FIG. 4 shows. On the visual level, it is the entire vertical line of disks (7) that then becomes darker and the scribe P3, which is transparent, adds transparency to the vertical line of disks (8) as said scribe P3 is mostly positioned in areas of non-transparency (9), which will be perceived by the eye of the observer as an amplified contrast fault.

FIG. 5 takes up the example of preceding FIG. 4, but this time the position of the scribes is optimized by following the directives of column (4) of the table of FIG. 2. The scribes P1 and P3 are positioned in the areas of transparency (IN, 6), that is to say substantially at the center and parallel to the parallel strips with high transparency (7,8), and the scribe P2 is positioned in an area of non-transparency (OUT), that is to say substantially at the center and parallel to the parallel strips with low transparency (9). ‘Parallel strips with high or low transparency’ is understood to mean the respective appearance of light or dark strips perceived by the observer who, being at a distance from the areas of transparency that is greater than the resolution capability of his eye, does not distinguish the content of said strips. In the example of FIGS. 4 and 5 above, said strips with high transparency (7,8) are formed by the alignment of the transparent disks (6), and said strips with low transparency (9) are formed by the spaces between the alignment of the transparent disks (6).

FIG. 6 illustrates a calculation method for calculating the distance d between the centers of two rows of disks (6) for a photovoltaic module that has to be made semitransparent by laser ablation. If R is the radius of the disks (6) and Cd is the distance between the disks, the geometric formula is:

$$d = \sqrt{3} ( R + \frac{Cd}{2} ) \qquad ( 1 )$$

If the width of each cell that forms the module, and therefore the distance between two consecutive lines P1, is L, the condition for the lines P1 and P3 to be positioned at the center of the patterns of transparency (6) at each interconnection is that the width L of each cell is proportional to the distance d:

$$L = kd = k \sqrt{3} ( R + \frac{Cd}{2} ) ( where k is an integer ) \qquad ( 2 )$$

In other words, the width L of each cell and the distance d between the geometric shapes of the areas of transparency (6) is given by the equation L=k d; k being an integer.

In one exemplary embodiment, if the transparency is achieved by lines of circular holes, the width of the cells L is fixed beforehand during the deposition of the layers by the scribes P1 formed in the TCO. The positioning of the scribes with respect to the strips with high or low transparency that are generally formed after the deposition of the thin films of the photovoltaic module is optimized for each interconnection by adjusting the radius R of the circular holes and the distance Cd between them depending on the degree of transparency. This optimization is performed via a simple algorithm known to those skilled in the art in such a way as to satisfy equation (2).

In a second exemplary embodiment that is comparable to the first, but in which the radius R of the circular holes and the distance Cd between them are determined beforehand depending on a fixed degree of transparency, the width L of the cells is then calculated before forming the insulation scribes P1 in such a way as to satisfy equation (2).

In the two previous scenarios, once the position of the scribe P1 is fixed, the scribes P2 and P3 are positioned depending on the dimensions R of the circular holes and on the distance Cd between the holes.

In a third scenario, the scribes are fixed beforehand during the deposition of the various layers that form the photovoltaic module, the scribe P2 being situated midway between the scribes P1 and P3. During the ablation process, their position is detected using a camera. In a second step, either the dimension of the geometric shapes of the areas of transparency or the distance between said shapes is corrected gradually over all of said shapes or alternatively over the shapes close to the scribes. This correction may be carried out using a program that controls the laser so as to position the strips with high transparency density at the insulation lines P1 and P3 and the strips with low transparency density at the line P2.

If the correction of the dimensions of the geometric shapes takes place over areas of transparency in the proximity of the scribes, two or three arrays of areas of transparency may appear rather than just one that is repeated over all of the cells.

FIG. 7 illustrates another example of optimized positioning of the scribes P1, P2 and P3 in an array of hexagonal holes. P1 and P3 are positioned in the areas of transparency (IN), that is to say substantially at the center and parallel to the parallel strips with high transparency (7,8), and P2 is positioned in an area of non-transparency (OUT), that is to say substantially at the center and parallel to the parallel strips with low transparency (9).

### Advantages of the Invention

Ultimately, the invention suitably meets the outlined aims by making it possible to improve the visual quality of a photovoltaic module (1) formed of a multitude of thin-film cells that are connected by electrical insulation and interconnection lines (P1,P2,P3); this improvement in the visual quality is achieved by making said electrical insulation and interconnection lines less visible, or even invisible, by positioning said lines (P1,P2,P3) in areas of transparency or of non-transparency with respect the similarity of their apparent colors.

1. A semitransparent photovoltaic module comprising:
firstly, a stack of thin films including at least one transparent thin film that has the function of a front electrode, a photovoltaic thin film that has the function of an absorber, and a metal thin film that has the function of a back electrode; said thin films being deposited on a transparent substrate; said photovoltaic module being divided into a plurality of cells (N,N+1, . . . N+x) that are electrically connected to one another by way of electrical interconnection lines forming the junction between the back electrode of the cell N and the front electrode of the cell N+1, and by way of electrical insulation lines forming the insulation between the back electrode of the cell N and of the cell N+1, and the insulation between the front electrode of the cell N and of the cell N+1;
secondly, a multitude of areas of transparency that are formed at least in said back metal electrode and in said absorber photovoltaic thin film; said areas of transparency all having the same geometric shape and being positioned with respect to one another so as to form one or more arrays that give rise to the visual appearance of a multitude of areas in the form of rectilinear strips whose longitudinal axes are parallel; some of said areas being positioned in strips having a high transparency density and some of said areas being positioned in a strip having a low transparency density,
wherein said electrical insulation lines are positioned in said rectilinear strips with high transparency density, and said electrical interconnection lines are positioned in said rectilinear strips with low transparency density, so as to reduce the visibility, to the naked eye, of said electrical interconnection and insulation lines.

2. The photovoltaic module as claimed in claim 1, wherein said geometric shape of the areas of transparency forming said ordered array are chosen from among the following shapes or in combinations thereof: disks, oval, polygonal, hexagonal and square surfaces.

3. The photovoltaic module as claimed in claim 1, wherein the width of said three electrical insulation and interconnection lines is less than 100 micrometers.

4. The photovoltaic module as claimed claim 1, wherein the distance between two consecutive electrical insulation or interconnection lines is greater than 100 micrometers.

5. The photovoltaic module (1) as claimed in claim 1, wherein the largest dimension of said geometric shapes of said areas of transparency is greater than 400 micrometers.

6. The photovoltaic module as claimed in claim 1, wherein said areas of transparency are separated by opaque areas that have dimensions of less than 100 micrometers.

7. The photovoltaic module as claimed in claim 1, wherein the relationship between the width L of each photovoltaic cell and the distance d between said areas of transparency is given by the equation L=k d; k being an integer.
